(19) United States
(12) Patent Application Publication
(10) Pub. No.: US 2018/0321293 A1
(43) Pub. Date: Nov. 8, 2018

(54) Multi-Purpose RF Test System

(71) Applicant: ELITE RF LLC, Hoffman Estates, IL (US)

(72) Inventors: Philip F. Aseltine, Arlington Heights, IL (US); Timothy M. Avicola, Crystal Lake, IL (US)

(21) Appl. No.: 15/966,907

(22) Filed: Apr. 30, 2018

Related U.S. Application Data
(60) Provisional application No. 62/492,514, filed on May 1, 2017.

(51) Int. Cl. G01R 29/08

(52) U.S. Cl. CPC G01R 29/0871

(57) ABSTRACT

A multi-purpose test system and method for testing RF products. The system includes a plurality of instruments housed within a test unit and a power supply or a power supply board, and/or a USB hub. The plurality of instruments includes two or more devices from the following: a spectrum analyzer, a signal generator, an oscilloscope, a tracking generator, a radio frequency power meter, one or more power amplifiers, a radio frequency relay, a coupler, and a radio frequency signal attenuator.

### CROSS-REFERENCES TO RELATED APPLICATIONS

The present application claims priority to provisional application No. 62/492,514 filed on May 1, 2017 and the subject matter of provisional application No. 62/492,514 is incorporated by reference herein in its entirety.

### FIELD OF THE INVENTION

The present invention relates to new products and methods for testing of RF equipment. The new products and methods are versatile, cost-effective, and easy to use.

### BACKGROUND OF THE INVENTION

Many products include a radio frequency (RF) component (otherwise referred to as “RF component”). Examples include telecommunications equipment (such as radio and television broadcasting equipment), avionics and radar systems, industrial and military equipment (such as industrial heaters and sealers that generate RF radiation to heat materials), medical imaging systems (such as magnetic resonance (MRI) systems or systems to destroy cancer cells), and even household products such as microwave ovens, cellular phones, cordless phones, etc. A radio frequency component is a component which generates electromagnetic waves in the radio frequency range. This range can be from around 20 KHz to about 300 GHz. An RF field has both an electric and a magnetic component (electric field and magnetic field). RF is also used to destroy cancer cells.

Because of the multitude of RF applications in the world, it is imperative that products and systems be able to operate properly in their environment without either being adversely affected by electromagnetic radiation in the environment or adversely affecting other equipment which utilizes RF technology. For example, if a cellular phone were to interfere with an MRI machine, this would create a safety hazard. Therefore, before a product or system is commercialized, it must be tested for RF immunity and emissions. For RF immunity testing, the equipment is exposed to RF disturbances and fields with various field strengths and frequency ranges, particularly those representative of their in-operation environment to ensure the equipment works in the presence of other RF emitting devices. Testing of RF emissions, on the other hand, is conducted to ensure that the RF equipment does not create RF disturbances and fields which adversely affect other instrumentation and equipment. Just like some equipment must be tested for fire safety, RF equipment must be tested for RF compatibility with the environment.

A number of pieces of equipment is necessary to conduct proper RF testing. The issue is that if a facility that is conducting the testing requires different pieces of equipment this has drawbacks in that getting all of the equipment is expensive and more complicated to use due to the different types of equipment available. There is a great need to reduce both the price and the complexity of RF testing.

### SUMMARY

The present invention is directed to a multi-purpose test system which can include a plurality of instruments housed within a test unit. The multi-purpose test system can include a power supply or a power supply board operably connected with one, two, three, four, five, or any number or all of the plurality of instruments. For example, the power supply or power supply board can be connected to any number from 1-9 instruments. The multi-purpose test system can include a USB hub operably connected with at least one, two, three, four, five, or any number or all of the plurality of instruments. For example, the power supply or power supply board can be connected to any number from 1-9 instruments. The instruments connected with the power supply or power supply board can be the same or different as the instruments connected with the USB hub. The plurality of instruments can include any one or more (such as 2, 3, 4, 5, 6, 7, 8, or 9) devices from the following: a spectrum analyzer, a signal generator, an oscilloscope, a tracking generator, a radio frequency power meter, one or more power amplifiers, a radio frequency relay, a coupler, and a radio frequency signal attenuator.

The multi-purpose test system can also include a central processing unit and software configured to control at least one of the plurality of instruments, such as any number from 1-9 or more of the instruments, such as any one or more of the following: a spectrum analyzer, a signal generator, an oscilloscope, a tracking generator, a radio frequency power meter, one or more power amplifiers, a radio frequency relay, a coupler, and a radio frequency signal attenuator. The multi-purpose test system can include a display operably connected with at least one of the plurality of instruments such as any number from 1-9 or more of the instruments, such as any one or more of the following: a spectrum analyzer, a signal generator, an oscilloscope, a tracking generator, a radio frequency power meter, one or more power amplifiers, a radio frequency relay, a coupler, and a radio frequency signal attenuator. In an embodiment, the test unit is configured to send outbound signals to and/or receive inbound signals from a product to be tested, and at least one of the plurality of instruments is configured to process the inbound signals from the product to be tested and to generate generated signals resulting from the processing of the inbound signals. Any number from 1-9 or more of the instruments are configured to process the inbound signals from the product to be tested and to generate generated signals resulting from the processing of the inbound signals, such as any one or more of the following: a spectrum analyzer, a signal generator, an oscilloscope, a tracking generator, a radio frequency power meter, one or more power amplifiers, a radio frequency relay, a coupler, and a radio frequency signal attenuator. The multi-purpose test system is also configured to show images in the display which represent the generated signals from at least one of the plurality of instruments, and this plurality of instruments can be any number from 1-9 or more of the instruments, such as any one or more of the following: a spectrum analyzer, a signal generator, an oscilloscope, a tracking generator, a radio frequency power meter, one or more power amplifiers, a radio frequency relay, a coupler, and a radio frequency signal attenuator.

In an embodiment, the display is external to the test unit, though it can be part of the test unit, or both. The multi-purpose test system is configured show on the display a plurality of windows which represent the generated signals from one or more of the plurality of instruments, and this plurality of instruments can be any number from 1-9 or more of the instruments, such as any one or more of the following: a spectrum analyzer, a signal generator, an oscilloscope, a tracking generator, a radio frequency power meter, one or more power amplifiers, a radio frequency relay, a coupler, and a radio frequency signal attenuator. The plurality of windows are selectively sizable, shapeable, and/or movable by a user. The multi-purpose test system is configured such that the user can choose which windows are shown on the display, such as windows associated with any one or more of the following: a spectrum analyzer, a signal generator, an oscilloscope, a tracking generator, a radio frequency power meter, one or more power amplifiers, a radio frequency relay, a coupler, and a radio frequency signal attenuator. Preferably, the central processing unit and the software are contained within the test unit, though they can be external too. The product to be tested is operably connected with the test unit in order to be tested.

The present invention is also directed to a method for testing a product in which at least one of the plurality of instruments is operably connected with the product, such as one or more of the following instruments: a spectrum analyzer, a signal generator, an oscilloscope, a tracking generator, a radio frequency power meter, one or more power amplifiers, a radio frequency relay, a coupler, and a radio frequency signal attenuator. The central processing unit and software are used to control at least one of the plurality of instruments, such as any one or more of: a spectrum analyzer, a signal generator, an oscilloscope, a tracking generator, a radio frequency power meter, one or more power amplifiers, a radio frequency relay, a coupler, and a radio frequency signal attenuator. The method can also include showing images on a display which reflect signals generated by at least one of the plurality of instruments, such as one or more of: a spectrum analyzer, a signal generator, an oscilloscope, a tracking generator, a radio frequency power meter, one or more power amplifiers, a radio frequency relay, a coupler, and a radio frequency signal attenuator. The method may include sending outbound signals from the test unit and/or receiving inbound signals from the product which is tested. Additionally, the method includes processing the inbound signals from the product which is tested, where the signals generated by the at least one of the plurality of instruments are generated based on the processing of the inbound signals, and such instruments are one or more of: a spectrum analyzer, a signal generator, an oscilloscope, a tracking generator, a radio frequency power meter, one or more power amplifiers, a radio frequency relay, a coupler, and a radio frequency signal attenuator.

The display is preferably external to the test unit, though there can be a display on the test unit and/or an external display as part of the multi-purpose test system. The method can include showing one or more windows on the display which represent the signals generated from one or more of the plurality of instruments. Such instruments can include one or more of: a spectrum analyzer, a signal generator, an oscilloscope, a tracking generator, a radio frequency power meter, one or more power amplifiers, a radio frequency relay, a coupler, and a radio frequency signal attenuator. The method can include selectively choosing which windows are displayed, and selectively modifying the size, shape, and/or location of the windows. Preferably, the central processing unit and the software are contained within the test unit.

### BRIEF DESCRIPTION OF THE DRAWINGS

FIG. 1 is a front perspective view of an exemplary RF test system 1 according to the present invention.

FIG. 2 is a plan view from the top of the RF test system 1 showing the components inside the case 9.

FIG. 3 is a front view of the RF test system 1 of the present invention.

FIG. 4 is a rear view showing the rear panel 200. The rear panel 200 is opposite to the front panel 3.

FIG. 5 is a schematic diagram showing the RF test system 1 connected with a product 500 to be tested via connection 502.

FIG. 6 is a schematic wiring diagram of the RF test system 1.

FIG. 7 is a schematic USB and HDMI cabling diagram of the RF test system 1.

FIG. 8 is a schematic coaxial cabling diagram of the RF test system 1.

Corresponding reference numbers indicate corresponding parts or elements throughout the several views of the drawings.

### DETAILED DESCRIPTION OF THE INVENTION

As stated above, there is a need to be able to reduce both the cost and the complexity to conduct RF testing and the present invention was designed with such purposes in mind. Specifically, the present invention is directed to a multi-purpose RF test system in which a single device is able to conduct a myriad of functions that are currently conducted by having a number of pieces of equipment. For example, if a laboratory needs to test an RF product and needs to use both a power amplifier and a spectrum analyzer, this would traditionally require having both a power amplifier and a spectrum analyzer. The present invention, for example, can include both a power amplifier and a spectrum analyzer as part of the same device, reducing cost and complexity to the laboratory. The present invention is, in essence, directed to a multi-purpose RF test system (otherwise referred to as the “RF test system”) that includes at least two functionalities though preferably, it includes many more such as three, four, five, or more.

One skilled in the art will appreciate that the novel equipment described herein can be used in other ways, such as to combine other types of equipment which are utilized in conjunction with one another.

All illustrations of the drawings are for the purpose of describing selected versions of the present invention and are not intended to limit the scope of the present invention.

The detailed description set forth below is intended as a description of some, but not all, of the configurations of the subject technology and is not intended to represent an exhaustive list. The detailed description includes specific details for the purpose of providing a thorough understanding of the present invention and subject technology. The subject invention and technology is not limited to the specific details set forth herein and may be practiced without these specific details. In other instances, well-known structures and techniques have not been shown or described in detail so as not to obscure the disclosure. Like parts are marked throughout the following description and drawings with the same reference numerals. The drawings may not be to scale and certain features may be shown exaggerated in scale or in somewhat schematic format in the interest of clarity, conciseness, and to convey information.

As used throughout, the singular forms “a,” “an,” and “the” include plural referents unless the context clearly indicates otherwise. Thus, for example, reference to a component can include two or more components unless the context indicates otherwise.

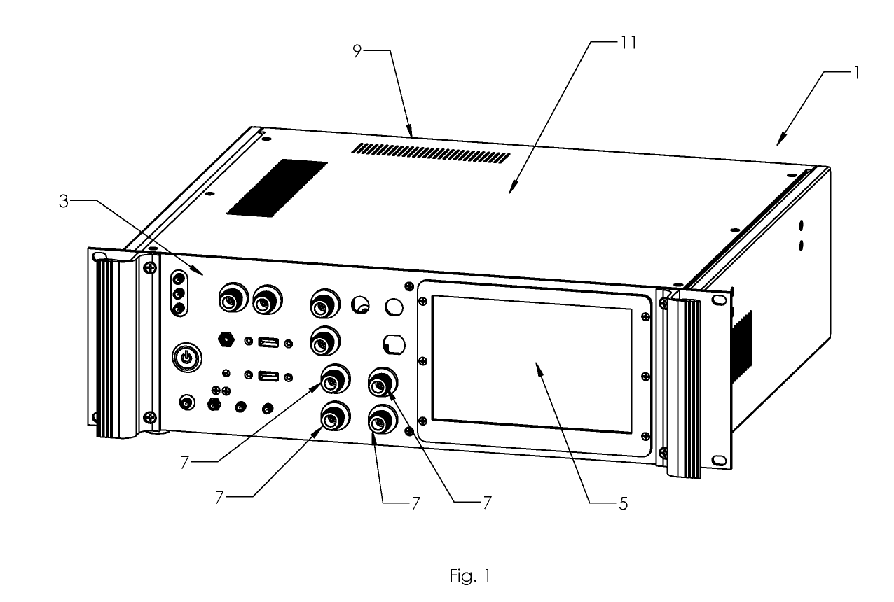

FIG. 1 is front perspective view of an exemplary RF test system 1 according to the present invention. On the front side 3 (otherwise referred to as the front panel 3), the RF test system 1 can include a front panel screen 5 or other output device which provides information to a user. The RF test system 1 can also include various connectors 7 for connecting with RF equipment to be tested by the RF test system 1. The RF test system 1 can be an equipment having a hard outer case 9 to protect sensitive electronic equipment inside of outer case 9 having a top portion 11 which is a flat and rigid surface. A reference to “test unit” means the case 9 and the components inside the case 9. The “RF test system 1” can be limited to the “test unit” though it does not have to be since an external monitor, for example, can be part of the RF test system 1.

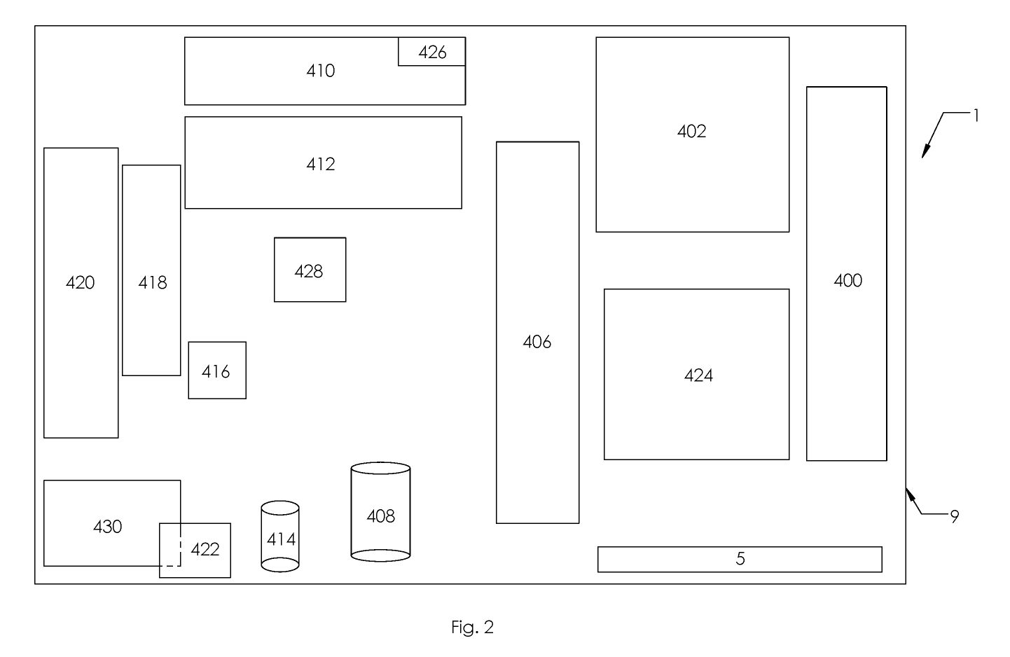

FIG. 2 is a plan view from the top of the RF test system 1 showing the components inside the case 9. FIG. 2 shows a tracking generator 400, an oscilloscope 402, a front panel display 5, a spectrum analyzer 406, an RF power sensor 408, a computer 410, a USB hub 412, an RF attenuator 414, a first power supply 420, a second power supply 418, a third power supply 416, an RF relay 422, a coupler 428, a signal generator 430, and a power amplifier 424, which are collectively referred to herein as “components”. The tracking generator 400, the oscilloscope 402, the spectrum analyzer 406, the signal generator 430, the RF power sensor 408, the RF attenuator 414, the RF relay 422, the coupler 428, and the power amplifier 424, are a subset of the “components” and are collectively referred to herein as “test instruments” or “testing instruments” or “testing devices” or “test devices” or “instruments”. It is noted that the terms “test instruments” or “testing instruments” or “testing devices” or “test devices” or “instruments” encompass instruments which directly test the output of a product to be tested as well as instruments which are ancillary to the testing. For example, a power meter receives an output of the product to be tested and tests it. A signal generator does not actually test an output of the product to be tested but does provide an input reference which is used for the testing. Similarly, a coupler does not directly test an output of a product under test though it can be part of the testing by sending a signal to a device that does do testing. For simplicity, they are all referred to as “test instruments”, etc.

The invention can include a multitude of various power amplifiers depending on frequency range, gain, and power output. The power amplifiers can be included in a single enclosure, or they can be included in different enclosures within case 9. The power amplifier 424 at FIG. 2 depicts the inclusion of one or more amplifiers in one structure. Additional structures can be added with additional power amplifiers. The power amplifier 424, for example, can include up to six power amplifiers or even more, preferably, up to four power amplifiers would be included. This is significant since the present invention can include not only a variety of testing instruments but also several power amplifiers in one relatively compact enclosure. Power amplifiers are normally bulky and expensive and would be difficult to include in a package of test instruments as in present invention, especially multiple power amplifiers in one enclosure which is included in the RF test system 1. Not all of the components need to be included inside the case 9. For example, the computer 410 can be external to the case 9. The present invention includes being able to control the RF test system 1 with the use of a laptop computer. Preferably, though, the computer 410 which controls the RF test system 1 is inside the case 9. The front panel display 5 can be excluded in favor of an external monitor, though preferably, the front panel display 5 will be included as well as an external monitor. The components shown at FIG. 2 are merely exemplary and the present invention includes having fewer or more components at the locations shown at FIG. 2 and different locations as those shown in FIG. 2.

Preferably, the computer 410 is configured to run a Windows operating system. The software 426 is preferably configured to run all of the components, especially the test instruments. For example, the computer 410 and software 426 are configured to run one or more or any combination of the following: the tracking generator 400, the oscilloscope 402, the front panel display 5, the spectrum analyzer 406, the RF power sensor 408, the USB hub 412, the RF attenuator 414, the first power supply 420, the second power supply 418, the third power supply 416, the RF relay 422, the coupler 428, the signal generator 430, and the power amplifier 424. More specifically, the computer 410 and software 426 are configured to run one or more or any combination of the following: the tracking generator 400, the oscilloscope 402, the front panel display 5, the RF relay 422, the spectrum analyzer 406, the RF power sensor 408, the RF attenuator 414, the signal generator 430, and the power amplifier 424.

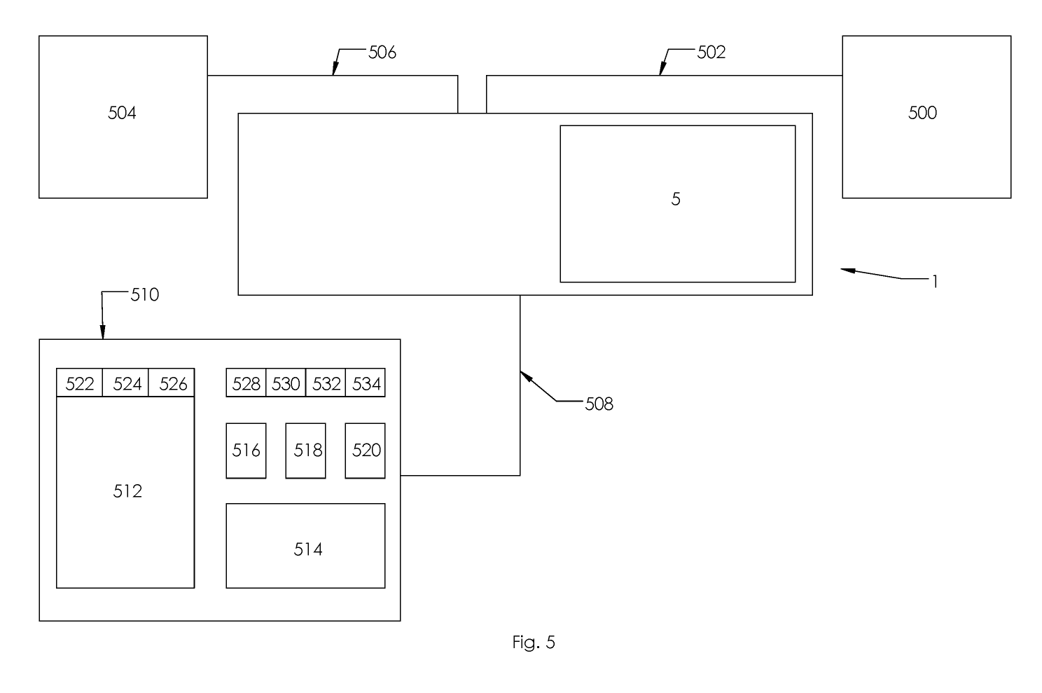

Some devices do not need to be directly run by the computer 410 and the software 426. For example, the coupler 428 and the attenuator 414 can be “pass through” devices which are not directly connected with the computer and whose functioning is not directly shown on the screen 5 or the external monitor 510. The power amplifier 424 may not need to be directly controlled by the computer 410 or software 426 since the signal generator 430 or even an external source such as the product to be tested may generate the input for the power amplifier 424 and the output of the power amplifier 424 can go to the spectrum analyzer 406. Thus, the control of the input and the output of the power amplifier 424 makes the control of the actual power amplifier unnecessary. Accordingly, if the coupler 428, the attenuator 414 and/or the power amplifier 424 are not directly controlled by the computer 410 and the software 426, then their functioning may not necessarily be directly reflected in a dedicated window on the screen 5. However, information for incidental devices such as the spectrum analyzer 406 would, in fact, give an indirect indication of the performance of the power amplifier 424. Preferably, any one or more and any combination of the following are run by the computer 410 and the software 426, and preferably have dedicated windows which reflect their operation on the screen 5 or external monitor 510 or other output device: The tracking generator 400, the oscilloscope 402, the spectrum analyzer 406, the RF power sensor 408, the RF relay 422, and the signal generator 430. The RF test system 1 (including the software 426 that is part of the RF test system 1) is configured to gather output signals from the test instruments and to generate a display of the signals on the front panel screen 5 and/or the external monitor 510 (see FIG. 5). Software 426 may include an executable computer program or other set of instructions that controls the RF test system 1, such as controlling when tests begin and end, the components, and/or controlling the display of results on the front panel screen 5 and/or the external monitor 510. For example, the software 426 can be built on a general-purpose PC platform running Windows 10, and allow independent control of the instruments. Each instrument can have a unique software application that runs on the computer 410 and can work with other software on the computer 410. As one example, a LabVIEW test program developed for the RF test system 1 can automatically control the internal instruments to provide a unique RF test environment. The LabVIEW environment can be viewed and controlled using the front panel display 5 or an external monitor, as well as a keyboard and/or mouse or any other input devices.

Not all of the components shown at FIG. 2 are necessary in the RF test system 1, since there are different options for the RF system 1 as requested by different customers. Preferably, the test instruments are “USB” test instruments, which are designed with a USB port (i.e., a Universal Serial Bus port) for communicating with other components in the RF test system 1. The software 426 in the RF system 1 that runs the test instruments is preferably software that can be run on a Windows operating system though this invention envisions the use of other operating systems as well. Below are various combinations of components that can be included in the RF test system 1. Combination 1: 1 Hz-4.4 GHz spectrum analyzer, 10 Hz-4.4 GHz RF tracking generator, 54 MHz-13.6 GHz dual signal generator, and 200 MHz 4 channel oscilloscope.

Combination 2: 1 Hz-4.4 GHz spectrum analyzer, 10 Hz-4.4 GHz RF tracking generator, 54 MHz-13.6 GHz dual signal generator, 500-4.2 GHz/5 watt RF power amplifier, 200 MHz 4 channel oscilloscope, and 50 MHz-4 GHz RF power meter.

Combination 3: 100 KHz-12.4 GHz spectrum analyzer, 100 KHz-12.4 GHz RF tracking generator, 54 MHz-13.6 GHz dual signal generator, and 200 MHz 4 channel scope.

Combination 4: 100 KHz-12.4 GHz spectrum analyzer, 100 KHz-12.4 GHz RF tracking generator, 54 MHz-13.6 GHz dual signal generator, 100 MHz-18 GHz RF/1 watt power amplifier, 200 MHz 4 channel scope, and 10 MHz-12.5 GHz RF power meter.

Combination 5: 6 GHz real-time spectrum analyzer, 20 GHz real-time spectrum analyzer, 6 GHz low harmonic signal generator, 6 GHz true RMS power sensor, 8 GHz peak and average power sensor, 20 GHz peak and average power sensor, 50 MHz-6 GHz 10 watt class AB power amplifier, 20 MHz-1 GHz 20 watt class A power amplifier, 20 MHz-2.7 GHz 10 watt class A power amplifier, 6 GHz-12 GHz 10 watt class AB power amplifier, 2 GHz-8 GHz 2 watt class A power amplifier, and 6 GHz-18 GHz 2 watt class A power amplifier.

The design of the components as shown at FIG. 2 are based on the expected use of the device as well as for a compact footprint and ease of manufacturing. For example, the oscilloscope 402 is a relatively large piece of equipment with various input and output channels. Preferably, it is positioned at the back of the RF test system 1 so it does not interfere with other components and its cables will not get in the way of other cables since it can simultaneously have up to four input channels plus the reference input. Moreover, a position near the edge of case 9 requires shorter cables to connect the oscilloscope 402 with the input devices outside of the case 9 and is therefore preferred. Also, the inputs of the oscilloscope 402 are in the back to provide more room on the front panel 3 for some of the other connectors 7 since the oscilloscope 402 has four input channels taking up space. In essence, this design provides more functionality.

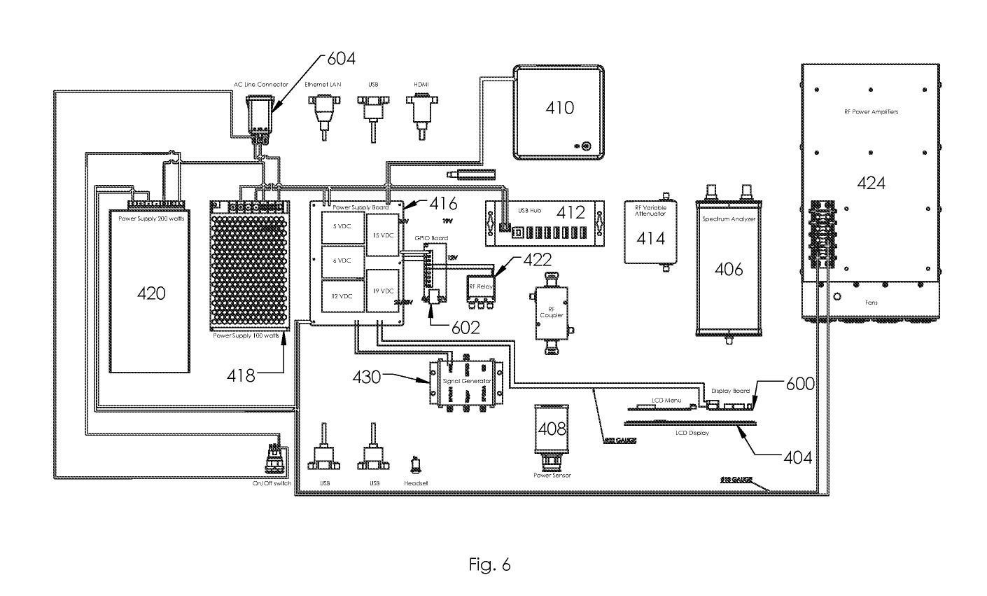

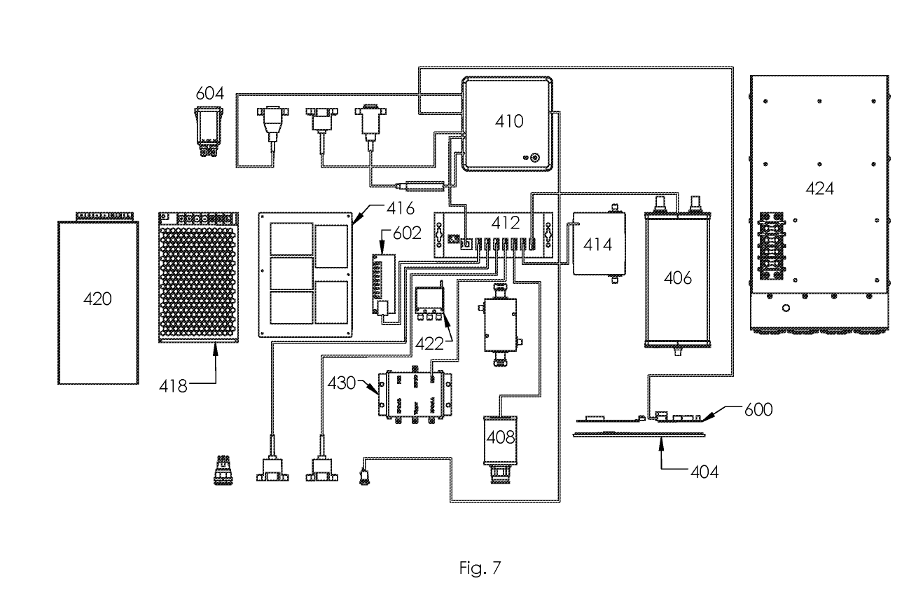

The RF test system 1 can include the spectrum analyzer 406, the RF tracking generator 400, the dual signal generator 430, the dual power RF amplifier 424, the four channel oscilloscope 402, the RF power meter 408 (also referred to as a power sensor), the RF relay 422 (which can be SPDT design), the RF attenuator 414, the front panel display 5, the computer 410, the USB hub 412, the first power supply 420, the second power supply 418, the third power supply 416, and the coupler 428. Broadly speaking, the spectrum analyzer 406 includes the capability to analyze an RF signal for properties at different frequencies, such as the amplitude as a function of frequency. The RF tracking generator 400 includes the capability to generate RF signals at the same frequencies as those received by the spectrum analyzer 406 in real time. The dual signal generator 430 has the capability to create one or two RF signals which can be used as inputs for equipment to be tested. The dual power RF amplifier 424 can amplify RF signals. The four channel oscilloscope 402 includes the capability to analyze RF signals for properties as a function of time, such as amplitude and frequency. The RF power meter 408 can measure the power of an inputted RF signal. The RF relay 422 can route RF signals to where they are desired such routing to particular equipment. The RF attenuator 414 includes being able to lower the power of an inputted RF signal. The coupler 428 includes being able to couple a lower level forward RF signal with a reverse RF signal which is inputted into the coupler. The front panel display 5 is an LCD or LED display, or other display configured to show the images of the testing of the equipment to be tested. The computer 410 is any computer capable of running the software to control the RF test system 1, and can be a general purpose computer such as those which run Windows operating systems or other operating systems. The USB hub 412 is a hub of USB ports that can be used as a hub and spoke type of system for communicating signals from one device and another as part of the RF test system 1. For example, as shown at FIG. 7, the spectrum analyzer 406 may be operably connected with the USB hub 412, and the USB hub 412 may be operably connected with the computer 410, which then makes the computer 410 operably connected with the spectrum analyzer 406 and capable of controlling the spectrum analyzer 406. The computer 410 may be connected with the USB hub with a USB connector or a non-USB connector. As shown at FIG. 6, the first power supply 420 is configured to be operably connected with an external power supply, such as an AC outlet. The first power supply 420 may provide more power than the second or third power supplies 418, 416, such as 200 watts. The second power supply 418 is configured to be operably connected with an external power supply, such as an AC outlet. The second power supply 418 may provide less power than the first power supply 420 and more than the third power supply 416, such as 100 watts. The third power supply 416 is configured to be operably connected with an external power supply, such as an AC outlet. The third power supply 416 may be a power supply board providing power at different voltages, such as 8 volts, 6 volts, 12 volts, 15 volts, and 19 volts. This is just an example of what can be included in an RF test system 1 and is not limited to these particular features and components. Additional or fewer test equipment can be part of the RF test system 1.

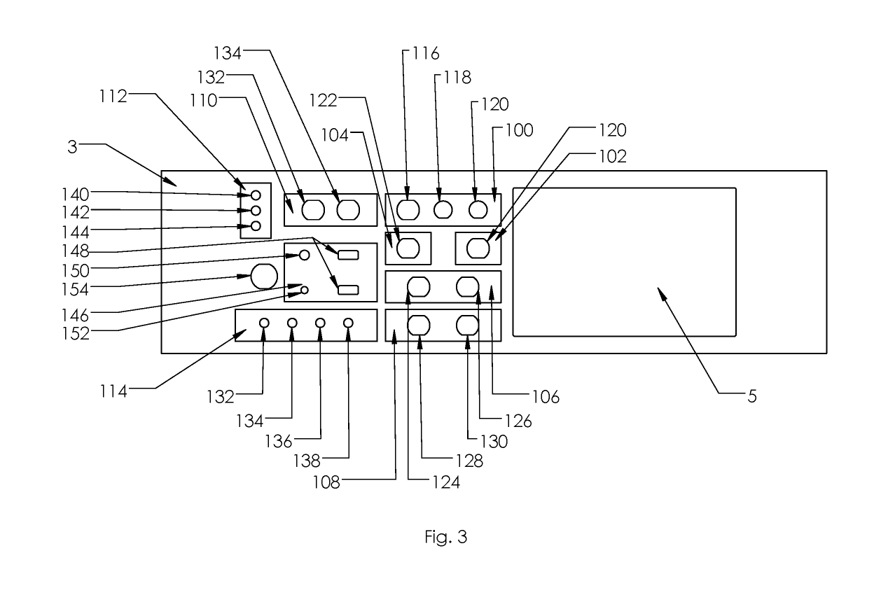

FIG. 3 is a front view of the RF test system 1 of the present invention. FIG. 3 shows, in more detail, the potential configuration of the front panel 3. FIG. 3 shows the front panel 3 and the output device 5. It also includes various “panels” for the different test equipment that is included as part of the RF test system 1. At FIG. 3 are shown a power sensor panel 100 operably connected with the power sensor 408, a tracking generator panel 102 operably connected with the tracking generator 400, a spectrum analyzer panel 104 operably connected with the spectrum analyzer 406, a first power amplifier panel 106 operably connected with power amplifier 424, a second power amplifier panel 108 operably connected with the power amplifier 424 (if it includes more than one power amplifier) or a different power amplifier, an attenuator panel 110 operably connected with the RF attenuator 414, an RF relay panel 112 operably connected with the RF relay 422, and a signal generator panel 114 operably connected with the signal generator 430.

The power sensor panel 100 includes RF input connector 116, Trig input connector 118, and Trig output connector 120, and is designed for utilizing the RF power meter 408 located inside of the RF test system 1. The RF input connector is configured to receive RF signals from the device which is being tested and to send those signals to the RF power meter 408. The Trig input connector 118 is a trigger input connector which synchronizes the RF measurement to the trigger. The Trig output connector 120 is a trigger output connector whose output is a signal which is synchronized to the RF input. The tracking generator panel 102 may include an RF output connector 120, and this output connector 120 is operably connected to the product to be tested and the signal from the product to be tested is then routed to the spectrum analyzer 406. The spectrum analyzer panel 104 may include an RF input connector 122 which is utilized to input the spectrum of the device being tested into the spectrum analyzer 406 inside the outer case 9. The first power amplifier panel 106 may include an input connector 124 and an output connector 126. The input connector 124 is configured to input RF signals which are then amplified by the first power amplifier 424 located inside the outer case 9 and then the amplified RF signals are sent through the output connector 126. The second power amplifier panel 108 contains input connector 128 and an output connector 130. The input connector 129 is configured to input RF signals which are then amplified by the second power amplifier 424 located inside the outer case 9 and then the amplified RF signals are sent through the output connector 130. Power amplifier 424 can include the first and the second power amplifiers in one enclosure.

The attenuator panel 110 includes an input connector 132 and an output connector 134. The input connector receives an RF signal that is communicated to the attenuator 414 which in turn reduces the power of the signal and then outputs the signal through the output connector 134. The RF relay panel 112 includes an NC connector 140, a COM connector 142, and a ND connector 144. NC stands for “normally closed” with no power to the relay. COM stands for “common” or the terminal shared between the CN and NO. NO stands for “normally open” with no power to the relay. These features are known in the art and no further explanation is necessary. The signal generator panel 114 includes Ref. I/O connector 132, RF Out B connector 134, Trigger connector 136, and RF Out A connector 138. The Ref I/O means a “reference input/output” and is used to stabilize the frequency of the signal generator 430. RF Out B means the second independent channel output of the signal generator 430. Having a Trigger connector allows the RF test system 1 to be connected with an external signal to turn the signal generator 430 output on and off RF Out A means the first independent channel output of the signal generator 430. The front panel 3 also includes communications panel 146, which includes two USB connectors 148, a headphone connector 150, and a infrared connector 152, which is an infrared receiver for a display remote to adjust the LCD screen attributes on the front panel screen 5. The USB connectors 148 can be used to add or update the software of the RF test system 1 through the computer 410 or an external computer. The USB connectors can also be used to connect with an external monitor to show test results on the screen of the external monitor, and to connect to an external storage device such as a flash drive, or any other USB memory device (i.e., a memory device that can be connected to USB ports) to store the test results of the RF test system 1. The front panel 3 can also include a power button 154 to turn the RF test system 1 on or off.

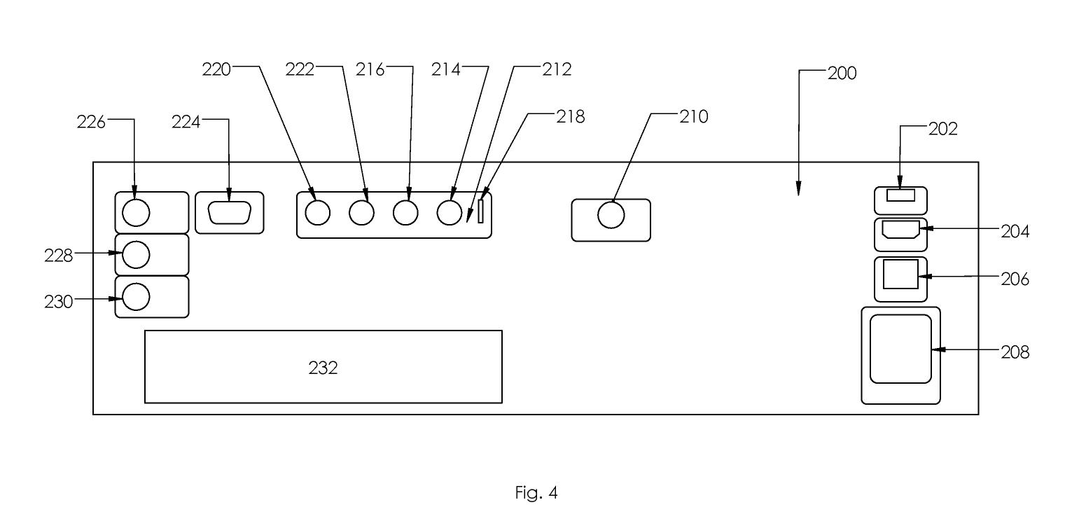

FIG. 4 is a rear view showing the rear panel 200. The rear panel 200 is opposite to the front panel 3. The rear panel 200 includes USB port 202, HDMI port 204, LAN (i.e., Local Area Network) connector 206, and power input 208. The rear panel also can include a button 210 to reset the computer 410 by turning it off and on. FIG. 4 also includes an oscilloscope panel 212 with four input channels operably connected to the oscilloscope 402 inside the outer case 9. The channels are CH1 220, CH2 222, CH3 216, and CH4 214, and they are connectors configured to receive up to four inputs into the oscilloscope 402. FIG. 4 also shows signal pin 218, which is used to calibrate the probes of the oscilloscope 402. FIG. 4 shows a serial port 224 which may be connected to a serial data device. FIG. 4 shows an input connector 228 for the spectrum analyzer 406 for receiving reference spectra. FIG. 4 also shows an input connector 230 for receiving reference spectra for the tracking generator 400. FIG. 4 also has a vent 232 to prevent the overheating of the RF test system 1.

FIG. 5 is a schematic diagram showing the RF test system 1 connected with a product 500 to be tested via connection 502. Connection 502 can be one or more connections depending on what is being tested, such as USB connections, coaxial cable connections, etc. The present invention can be used to simultaneously test more than one component and FIG. 5 shows a second product 504 to be tested. The output of the testing can be displayed in the front panel display 5 and/or in an external monitor 510 via connection 508, which can be any suitable connection such as USB or HDMI (e.g., High-Definition Multimedia Interface). The external monitor 510 can be the screen of a laptop computer, a television, or a stand-alone monitor, such as an LCD or LED monitor. Preferably, it is a stand-alone monitor to reduce the footprint utilized while improving the usability of the RF test system 1 when the output of multiple components is desired at the same time, especially since the stand-alone monitor would be larger than the screen of a laptop. It is also possible to use more than one external monitor 510 if that is desired, such as two stand-alone monitors or a laptop and a stand-alone monitor.

On the external monitor 510 (as well as the front panel screen 5) are shown one or more of various windows 512, 514, 516, 518, 520. These windows show the output of the various test devices, such as the results of testing the products to be tested 500 and 504. These windows are movable and/or resizable and/or re-shapeable and the user can select which ones to show and which ones not to show, and how they will look. The comprehensive display as a whole may be sized and shaped by a user as desired. The external monitor 510 (as well as the front panel screen 5) can also display tabs 522, 524, 526, 528, 530, 532, and 534. These tabs (or “soft keys”) are utilized to operate the various test devices and the RF test system 1 in general. The tabs can also be movable and/or resizable and/or re-shapeable.

The user can create and save different formats for different types of testing. For example, if on a particular day, the user tests the performance of an MRI machine, the user can set up the appropriate window and tab formatting that is best for testing the performance of the MRI machine and save those preferences. If on a subsequent day, the user tests something else, and then subsequently the user tests an MRI machine again, the user can go back to the saved MRI preferences to re-set the desired format of the windows and tabs and size to save the time of having to re-format the output characteristics of the external monitor 510 and/or the front panel screen 5. This makes this product easy to use, convenient, and a huge time saver. Thus, the user can select the configuration that is most convenient and effective for the needs of the user and save it for future use by that user or by other users. This is not possible with traditional systems which are designed for showing the test results of a single instrument on a screen and have a predetermined format and size. Additionally, in the present invention, users can set up their own individual preferences and save them in the system, such as MRI set up 1 or MRI set up 2. Different people have different needs such as different eyesight and some may be color blind so being able to customize the system and save it can allow people to quickly return to their preferred settings for use of the equipment.

Even if someone were to try to connect various USB devices into one output screen, it would difficult to do so if the software from the USB devices is designed to show windows and other information of a particular format and size that is not flexible to accommodate the display of test results of different test equipment simultaneously. In fact, if any one of the USB devices were to have a predetermined format and size, this would make it inconvenient or impossible for a user to utilize the screen to run multiple test equipment simultaneously. Thus, in the present invention, preferably, all of the test equipment has software that can be run by the computer 410 and which has resizable and/or movable and/or selectable windows, tabs, and controls displayed in the external monitor 510 (and front panel screen 5).

Traditional testing equipment, such as a spectrum analyzer, is basically a big expensive box with a screen and many physical keys, as well as a processor to process the software to run the spectrum analyzer. This is cumbersome and complicated, and only allows the user to use the particular test device currently in use, such as a spectrum analyzer. If for example, an additional test device were needed, such as a power amplifier, this would also require a big box with a screen and “hard controls” and a processor to run the power amplifier. The user would therefore need the item to be tested as well as two big and expensive boxes on their lab bench and hard controls on both devices which are run separately. The RF test system 1 utilizes a single computer 410 to run all of the test devices that form part of the RF test system 1 and has soft keys to run all of the devices easily and with much functionality. The software to run the test equipment is preferably inside the computer 410 though it can be outside of the computer 410 and be operably connected with the computer 410. Any type of memory storage is acceptable for the software such as ROM and/or RAM, preferably it is ROM since this is non-volatile and will remain in the system even if the power is turned off. Moreover, any hardware can be used to store the software such as a hard drive (with moving parts) or a solid state drive (no moving parts), or an optical drive, etc.

Even less expensive and compact systems which try to utilize the processor of an external computer to run the test devices would be inconvenient since the test devices would still have many hard controls and the footprint would still be inefficient because now the user would have, for example, a spectrum analyzer and a power amplifier as well as another computer to run the software. This is quite different from the present invention where a single device with a single computer inside the device runs all of the software and does all of the processing to run a myriad of devices. In the present invention, the computer can be operably connected with an external monitor that can be used (through “soft keys”) to run the various equipment with any input device such as a keyboard (wireless or wired), a mouse (wireless or wired), a touch-sensitive screen, a gesture-responsive interface, or any other input device. The term “soft keys” is used to denote icons, windows, tabs, and other visual graphics that are shown on front panel screen 5 and/or the external monitor 510, and/or any other visual output. The “soft keys” can be manipulated by a user such as by clicking on the graphics with a mouse, typing into boxes, using command keys, and/or using a touch screen, or touch pad, etc. Basically, “soft keys” are a way to control the RF test system 1 by using graphical user interfaces and/or other interfaces via input devices such as mice, keyboards, touch pads, touch screens, etc. instead of using physical buttons on the RF test system 1. The external monitor can be put on top of the case 9 since the top surface 11 of the case 9 is flat and hard and has no buttons or connectors (see FIG. 1), for ease of visibility and reduction of footprint. Moreover, the ability to use the external monitor 510 allows the ability to have multiple windows that can be easily seen by the user. If a laptop were used, or even the front panel screen 5, to see the test results from the test equipment, it would be difficult to see multiple windows due to the small size. In the present invention, information for 1-10 or more, such as 1-8 test instruments can be included in the external monitor and be readable by a typical user. The present invention does not need a separate processor or software for each test device nor does it need an external computer to run any software. Except for an on/off button or a button to reset the internal computer, there is no need for hard keys. Thus, the RF test system 1 can include one or two or three or four or five hard keys to run the RF test system 1 and the rest can be soft keys, making the device simpler, less expensive, and easier to use. Preferably, there are no hard keys on the RF test system 1 and everything is run with soft keys.

In an embodiment, during operation, the appropriate test instruments would be connected (directly or indirectly) with the product 500 to be tested. The term “operably connected” means to be connected directly or indirectly. The appropriate test instruments would then obtain a measurement associated with the product 500 under test. Each of the test instruments generates an output signal representing the measurement obtained. This output is then reflected in the front panel screen 5 and the external monitor 510.

FIG. 6 shows the wiring diagram of the RF test system 1. The components identified at FIG. 6 are the same as at FIG. 2 if they are identified by the same numbers. FIG. 6 also shows the display board 600 which is used to show images on the display 5. FIG. 6 also shows GPIO (general purpose input/output) board 602, which controls the RF relay in conjunction with the computer 410. and AC line connector 604 which provides external power to the RF test system 1. The wiring diagram shows how power is distributed in the RF test system 1. Not all of the components inside case 9 nor all of the wires that carry power are necessarily shown at the wiring diagram at FIG. 6. For example, the spectrum analyzer 406 is powered by a USB cable which also serves to transmit data to and/or from the spectrum analyzer 406.

FIG. 7 shows the USB and HDMI cabling diagram of the RF test system 1. The components identified at FIG. 7 are the same as at FIGS. 2 and 6 if they are identified by the same numbers. The USB and HDMI cabling diagram shows how different components are connected with each other and externally to the RF test system 1 for transferring signals from one component to another. Not all of the components inside case 9 nor all of the USB and HDMI cables in the RF test system 1 are necessarily shown at the USB and HDMI cabling diagram at FIG. 7.

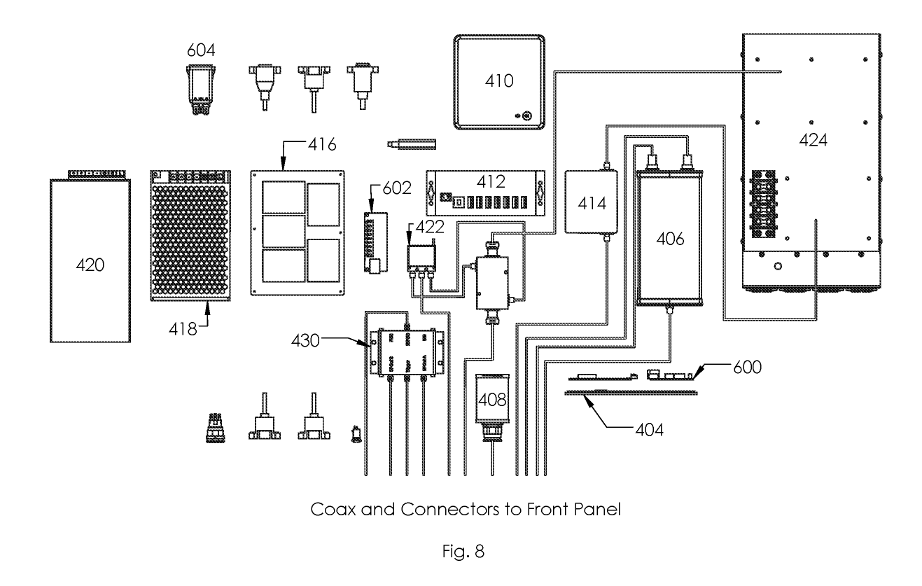

FIG. 8 shows the coaxial cabling diagram of the RF test system 1. The components identified at FIG. 8 are the same as at FIGS. 2 and 6 if they are identified by the same numbers. The coaxial cabling diagram shows how different components are connected with each other and externally to the RF test system 1 for transferring signals from one component to another and externally to the RF test system 1. Not all of the components inside case 9 nor all of the coaxial cables in the RF test system 1 are necessarily shown at the coaxial cabling diagram at FIG. 8.

### Example 1

It was desired to test a power amplifier's harmonic performance using the Elite RF S-Series RF test system. The RF test system was “set up”, which means put on a bench in close proximity to the power amplifier to be tested and plugged into a power source. The RF test system was also connected with an external monitor which is larger than the screen of the RF test system. The power amplifier to be tested was a 900 MHz, 65 W power amplifier. The power amplifier to be tested was connected to a power supply to operate the device and was also connected to a source of RF signals. The power amplifier may be connected with an attenuator to lower the power of the signal to a level that is compatible with the spectrum analyzer input level prior to sending the signal to the spectrum analyzer. The attenuator may be part of the power amplifier, or separate, or it can be inside the RF test system case. The power amplifier to be tested was therefore operably connected with the RF test system. In this example, the amplifier is outputting RF at 10 watts and 915 MHz. The harmonic performance of the amplifier to be tested was measured with the spectrum analyzer located inside the RF test system. To measure the harmonic performance, the output of the power amplifier to be tested was connected with the RF input connector of the spectrum analyzer via one or more attenuators. The result showed fundamental frequency at the highest level followed by harmonics of a lower level. Since the harmonics are lower than the fundamental, we know that it worked.

### Example 2

It was desired to set up and calibrate a power amplifier to be tested. This particular power amplifier coves 500 to 2500 MHz and provides 25 watts of output power. The RF test system was “set up”, which means put on a bench in close proximity to the power amplifier to be tested and plugged into a power source. The RF test system was also connected with an external monitor which is larger than the screen of the RF test system. The power amplifier to be tested was connected to a power supply to run the power amplifier. The power amplifier to be tested was also connected with the RF test system. The power amplifier was calibrated using the built-in functions of the RF test system. To calibrate the power and detected voltage across the frequency band of 500 to 2500 MHz, the test setup used the signal generator and power meter with a custom program written to store the detected voltage versus power and frequency in the memory of the RF test system. The RF test system can use random access memory for this type of activity, or non-volatile memory such as a “hard disk drive” which has moving parts, or a solid state device or “flash drive” which does not have moving parts. In this case, the storage device was used and it was a solid state device. In this Example, an RF switching relay was connected to the RF output of the amplifier being tested. The switching relay then was capable of routing the RF output of the amplifier being tested to either the power meter or the spectrum analyzer of the RF test system in order to “build” the data of the voltage versus power and frequency in the memory of the RF test system. The signal generator was connected to the RF input of the power amplifier being tested and therefore supplied the signals that are used to test the power amplifier. Those signals were amplified by the power amplifier and then outputted from the RF output of the power amplifier being tested and then routed back to the RF test system either to the power meter or spectrum analyzer. The power meter measured the output power and gain since the RF test system utilized the signal generator to generate the original signal being amplified so the RF test system had the reference power used to calculate the gain. The spectrum analyzer measured the harmonic and spurious signal levels of the RF output of the power amplifier and provided an output in this respect.

The information provided from the RF test system was used to calibrate the power amplifier per the instructions of the power amplifier. When the RF test system determines that a specific power output is reached, the RF test system sends the calibration data to the amplifier to be stored in non-volatile memory, thus calibrating the amplifier which is being tested/calibrated. Since calibrating the power amplifier was done with the RF test system, the power amplifier was easily connected with the RF test system and therefore was connected with the spectrum analyzer, the signal generator, and the power meter at the same time with a small footprtint. This was very convenient and an improvement over having to connect the power amplifier to a separate spectrum analyzer, a separate signal generator, and a separate power meter. Moreover, since the test equipment (e.g., the spectrum analyzer, the signal generator, and the power meter) are all part of the same RF test system, and they were used together to calibrate the power amplifier, the chance of an error occurring was significantly reduced since the different test equipment are part of the same system and are designed to communicate with the RF test system in a consistent manner. Thus, setup of the equipment was easy and issues with incompatibility were essentially non-existent.

The screen of the RF test system is capable of simultaneously showing in real time the test results of one or more of the signal generator, the power meter, and the spectrum analyzer, and to toggle between the three, as desired by the user. For example, the screen of the RF test system can be shown and tiled on the screen and/or on the external monitor. The ability to use an external monitor was convenient since tiling three different results from three different tests can create a crowded view on the screen of the RF test system so the ability to use an external monitor (or more than one) is very convenient. The user can decide whether to show the results of one testing equipment, such as the spectrum analyzer, or all of them, such as the spectrum analyzer, signal generator, and power meter, or any combination. For example, if it is desired to get a closer view of the amplifier's harmonics, the user can choose to only display the information from the spectrum analyzer. In this case, all three were desired so the RF test system provided real-time information from the spectrum analyzer, the power meter, and the signal generator at the same time. The results of the calibration were cross checked against a separate independent system and the results correlated.

### Example 3

The RF test system was also used to conduct scalar network analysis. The spectrum analyzer and signal generator can be combined to create a scalar network analyzer, to measure the insertion loss of a filter, attenuator or amplifier. If used with a directional coupler, this test setup also measures return loss. In this case, it was desired to measure the insertion loss of a filter. Thus, the equipment to be tested was a filter. The signal generator generated an RF output. The output of the signal generator was connected with the input of the filter to be tested. The output of the filter was connected with the input of the spectrum analyzer. Both the RF test system and the filter were connected to power source(s) and turned on. The RF test system displayed both the parameters of the RF signal generated by the signal generator as well as the output from the filter (as measured by the spectrum analyzer) to determine the insertion loss of the filter. If a directional coupler had been used between the output of the signal generator and the input of the filter, part of the reflection of power from the filter back to the signal generator could have been diverted by the directional coupler to the spectrum analyzer instead of the output of the filter being connected to the spectrum analyzer, and then the spectrum analyzer would have measured the return loss. The results of the RF test system correlated with the data received from the manufacturer of the filter so this example worked.

### Example 4

The equipment to be tested is a signal generator. This is not the signal generator that is part of the RF test system. Rather, this is a separate piece of equipment that is being tested for noise, by the RF test system being used to conduct a phase noise measurement. The phase noise measurement of a signal generator at 1 and 4 GHz carriers was conducted. Both the RF test system and the signal generator to be tested were connected to power and turned on. The output of the signal generator was connected to the input of the spectrum analyzer on the RF test system. The spectrum analyzer displayed the single-sideband phase noise on a logarithmically-scaled spectrum plot. The results showed that the signal generator met its specified requirements.

### Example 5

Another solution that was provided by the RF test system is that of digital demodulation. Complex communications signals that sometimes cannot be described as AM or FM need to be analyzed to determine what they are. This can be done by demodulation of a digitally-modulated RF signal by using the spectrum analyzer as a vector signal analyzer (VSA). The RF signal that is to be tested was channeled into the input of the spectrum analyzer. The output was shown on the screen of the RF test system as well as an external monitor. The results successfully showed a demodulation of the complex signal. The built-in software of the EF test system offers common VSA views, such as constellation diagrams, symbol-error charts and symbol tables. The system software demodulates ASK, BPSK, DBPSK, QPSK, DQPSK, 8PSK, DBPSK, π/4 DQPSK, OQPSK, N-FSK and 16-QAM.

Headings and subheadings, if any, are used for convenience only and do not limit the invention. Any aspect set forth in any embodiment or example may be used with any other embodiment or example set forth herein. It will be apparent to those skilled in the art that various modifications and variations can be made in the disclosed products and processes without departing from the scope of the disclosure. Other examples of the disclosure will be apparent to those skilled in the art from consideration of the specification and practice of the disclosure disclosed herein. It is intended that the specification and examples be considered as exemplary only and that the present invention is not limited to the details shown. It is expressly intended, for example, that all ranges broadly recited in this document include within their scope all narrower ranges and points which fall within the broader ranges.

All structural and functional equivalents to the elements of the various aspects described throughout this disclosure that are known or later come to be known to those of ordinary skill in the art are expressly incorporated herein by reference and are intended to be encompassed by the claims. Furthermore, to the extent that the term “include,” “have,” or the like is used in the description or the claims, such term is intended to be inclusive in a manner similar to the term “comprise” as “comprise” is interpreted when employed as a transitional word in a claim.

1. A multi-purpose test system, comprising:
a plurality of instruments housed within a test unit; and
a power supply or a power supply board and/or a USB hub, wherein
the plurality of instruments comprises two or more devices selected from the group consisting of: a spectrum analyzer, a signal generator, an oscilloscope, a tracking generator, a radio frequency power meter, one or more power amplifiers, a radio frequency relay, a coupler, and a radio frequency signal attenuator.

2. The multi-purpose test system according to claim 1, further comprising: a central processing unit and software configured to control at least one of the plurality of instruments.

3. The multi-purpose test system according to claim 1, further comprising a display operably connected with at least one of the plurality of instruments.

4. The multi-purpose test system according to claim 3, wherein the test unit is configured to send outbound signals to and/or receive inbound signals from a product to be tested, the at least one of the plurality of instruments is configured to process the inbound signals from the product to be tested and to generate generated signals resulting from the processing of the inbound signals, and wherein the multi-purpose test system is configured to show images in the display which represent the generated signals from the at least one of the plurality of instruments.

5. The multi-purpose test system according to claim 4, wherein the display is external to the test unit, and wherein the multi-purpose test system is configured show on the display a plurality of windows which represent the generated signals from the at least one of the plurality of instruments, and wherein the plurality of windows are selectively sizable, shapeable, and/or movable by a user, and wherein the multi-purpose test system is configured such that the user can choose which windows are shown on the display.

6. The multi-purpose test system according to claim 2, wherein the central processing unit and the software are contained within the test unit.

7. The multi-purpose test system according to claim 1, wherein the plurality of instruments comprises three or more devices selected from the group consisting of: the spectrum analyzer, the signal generator, the oscilloscope, the tracking generator, the radio frequency power meter, the one or more power amplifiers, the radio frequency relay, the coupler, and the radio frequency signal attenuator.

8. The multi-purpose test system according to claim 1, wherein the plurality of instruments comprises the spectrum analyzer, the dual signal generator, and the oscilloscope.

9. The multi-purpose test system according to claim 1, further comprising the product to be tested operably connected with the test unit.

10. A method for testing a product, comprising:
providing a multi-purpose test system which comprises a plurality of instruments housed within a test unit and which comprises a power supply or a power supply board and/or a USB hub, wherein the plurality of instruments comprises two or more devices selected from the group consisting of: a spectrum analyzer, a signal generator, an oscilloscope, a tracking generator, a radio frequency power meter, one or more power amplifiers, a radio frequency relay, a coupler, and a radio frequency signal attenuator, the method further comprising operably connecting the at least one of the plurality of instruments with the product.

11. The method according to claim 10, further comprising controlling the at least one of the plurality of instruments with a central processing unit and software.

12. The method according to claim 10, further comprising showing images on a display which reflect signals generated by the at least one of the plurality of instruments.

13. The method according to claim 12, further comprising sending outbound signals from the test unit and/or receiving inbound signals from the product.

14. The method according to claim 13, further comprising processing the inbound signals from the product, wherein the signals generated by the at least one of the plurality of instruments are generated based on the processing of the inbound signals.

15. The method according to claim 12, wherein the display is external to the test unit, and wherein showing images on the display comprises showing one or more windows which represent the signals generated from the at least one of the plurality of instruments, the method further comprising selectively choosing which windows are displayed, and selectively modifying the size, shape, and/or location of the windows.

16. The method according to claim 11, wherein the central processing unit and the software are contained within the test unit.

17. The method according to claim 10, wherein the plurality of instruments comprises three or more devices selected from the group consisting of: the spectrum analyzer, the signal generator, the oscilloscope, the tracking generator, the radio frequency power meter, the one or more power amplifiers, the radio frequency relay, the coupler, and the radio frequency signal attenuator.

18. The method according to claim 10, wherein the plurality of instruments comprises the spectrum analyzer, the dual signal generator, and the oscilloscope.
